(19) United States
(12) Patent Application Publication
(10) Pub. No.: US 2025/0157516 A1
(43) Pub. Date: May 15, 2025

(54) MAGNETIC MEMORY DEVICE

(71) Applicant: Samsung Electronics Co., Ltd., Suwon-si (KR)

(72) Inventors: Yongjae Lee, Suwon-si (KR); Kilho Lee, Suwon-si (KR); Ung Hwan Pi, Suwon-si (KR)

(21) Appl. No.: 18/925,376

(22) Filed: Oct. 24, 2024

(30) Foreign Application Priority Data
Nov. 9, 2023 (KR) 10-2023-0154269

(51) Int. Cl. G11C 11/16; G11C 19/08; H10B 61/00; H10N 50/85

(52) U.S. Cl. CPC G11C 11/161; G11C 19/0808; H10B 61/00; H10N 50/85

(57) ABSTRACT

A magnetic memory device comprising a substrate, a first dielectric pattern on the substrate, a dielectric pillar including a penetration part that penetrates the first dielectric pattern and a protrusion part that protrudes above a top surface of the first dielectric pattern, a first magnetic pattern between the first dielectric pattern and the dielectric pillar and including a first part that surrounds a lateral surface of the penetration part and a second part that surrounds a lateral surface of the protrusion part, a second magnetic pattern on the first dielectric pattern and surrounding a lateral surface of the second part, and a tunnel barrier pattern on the first dielectric pattern and between the second part and the second magnetic pattern. The first magnetic pattern extends in a third direction perpendicular to a top surface of the substrate.

### CROSS-REFERENCE TO RELATED APPLICATION

This U.S. nonprovisional application claims priority under 35 U.S.C § 119 to Korean Patent Application No. 10-2023-0154269 filed on Nov. 9, 2023, in the Korean Intellectual Property Office, the disclosure of which is hereby incorporated by reference in its entirety.

### BACKGROUND

The present inventive concepts relate to magnetic memory devices, and more particularly, to magnetic memory devices that uses motion of magnetic domain walls.

As electronic devices trend toward higher speed and lower power consumption, high-speed read/write operations and low operating voltages are increasingly important for memory devices incorporated therein. In order to meet demands placed on memory devices, magnetic memory devices have been developed as memory devices. Since magnetic memory devices may operate at high speed and may have nonvolatile characteristics, it has attracted considerable attention as a potential next-generation memory device. In particular, new magnetic memory devices have recently been studied and developed to use the motion of magnetic domain walls in magnetic materials.

### SUMMARY

Some embodiments of the present inventive concepts provide a vertical magnetic memory device exhibiting improved electrical properties and increased reliability.

Some embodiments of the present inventive concepts provide a vertical magnetic memory device for which mass production may be more easily achieved.

According to some embodiments of the present inventive concepts, a magnetic memory device may comprise: a substrate; a first dielectric pattern on the substrate; a dielectric pillar including a penetration part that penetrates the first dielectric pattern and a protrusion part that protrudes from a top surface of the first dielectric pattern; a first magnetic pattern between the first dielectric pattern and the dielectric pillar, the first magnetic pattern including a first part that surrounds a lateral surface of the penetration part and a second part that surrounds a lateral surface of the protrusion part; a second magnetic pattern on the first dielectric pattern, the second magnetic pattern surrounding a lateral surface of the second part; and a tunnel barrier pattern on the first dielectric pattern and between the second part and the second magnetic pattern. The first magnetic pattern may extend along a third direction perpendicular to a top surface of the substrate.

According to some embodiments of the present inventive concepts, a magnetic memory device may comprise: a substrate; a first dielectric pattern on the substrate; and a plurality of vertical structures that penetrate the first dielectric pattern. The vertical structures may be spaced apart from each other in a first direction and a second direction that are parallel to a top surface of the substrate and intersect each other. Each of the vertical structures may include: a dielectric pillar including a penetration part that penetrates the first dielectric pattern and a protrusion part that protrudes from a top surface of the first dielectric pattern; a first magnetic pattern between the first dielectric pattern and the dielectric pillar, the first magnetic pattern including a first part that surrounds a lateral surface of the penetration part and a second part that surrounds a lateral surface of the protrusion part; a second magnetic pattern on the first dielectric pattern, the second magnetic pattern surrounding a lateral surface of the second part; and a tunnel barrier pattern on the first dielectric pattern and between the second part and the second magnetic pattern. Each of the first magnetic patterns may extend along a third direction perpendicular to the top surface of the substrate.

According to some embodiments of the present inventive concepts, a magnetic memory device may comprise: a substrate including a first wiring layer that extends in a second direction; a first dielectric pattern on the substrate; a dielectric pillar on the first wiring layer, the dielectric pillar including a penetration part that penetrates the first dielectric pattern and a protrusion part that protrudes from a top surface of the first dielectric pattern; a first magnetic pattern between the first dielectric pattern and the dielectric pillar on the first wiring layer, the first magnetic pattern including a first part that surrounds a lateral surface of the penetration part and a second part that surrounds a lateral surface of the protrusion part; a second magnetic pattern on the first dielectric pattern, the second magnetic pattern surrounding a lateral surface of the second part; a tunnel barrier pattern on the first dielectric pattern and between the second part and the second magnetic pattern; a second dielectric pattern on the first dielectric pattern, the second dielectric pattern surrounding a lower lateral surface of the second magnetic pattern on the first dielectric pattern; a second wiring layer on the second dielectric pattern, the second wiring layer surrounding an upper lateral surface of the second magnetic pattern; and an upper dielectric pattern that covers a top surface of the tunnel barrier pattern, a top surface of the second magnetic pattern, and a top surface of the second wiring layer. The first magnetic pattern may extend along a third direction perpendicular to a top surface of the substrate.

### BRIEF DESCRIPTION OF DRAWINGS

FIG. 1 illustrates a plan view showing a magnetic memory device according to some embodiments of the present inventive concepts.

FIGS. 2A and 2B illustrate cross-sectional views respectively taken along lines A-A′ and B-B′ of FIG. 1, showing a magnetic memory device according to some embodiments of the present inventive concepts.

FIG. 3A illustrates a cross-sectional view taken along line A-A′ of FIG. 1.

FIG. 3B illustrates a cross-sectional view taken along line B-B′ of FIG. 1.

FIG. 4 illustrates an enlarged view showing section A of FIGS. 3A and 3B.

FIGS. 5 to 14 illustrate cross-sectional views showing a method of fabricating a magnetic memory device depicted in FIGS. 3A and 3B.

FIGS. 15 to 18 illustrate cross-sectional views showing a method of fabricating a magnetic memory device depicted in FIGS. 3A and 3B.

FIGS. 19 and 20 illustrate cross-sectional views showing a magnetic memory device according to some embodiments of the present inventive concepts.

FIGS. 21 and 22 illustrate cross-sectional views showing a method of fabricating a magnetic memory device depicted in FIG. 20.

FIG. 23 illustrates a cross-sectional view showing a magnetic memory device according to some embodiments of the present inventive concepts.

FIGS. 24 to 27 illustrate cross-sectional views showing a method of fabricating a magnetic memory device depicted in FIG. 23.

### DETAILED DESCRIPTION

The following will now describe in detail some examples of embodiments of the present inventive concepts with reference to the accompanying drawings.

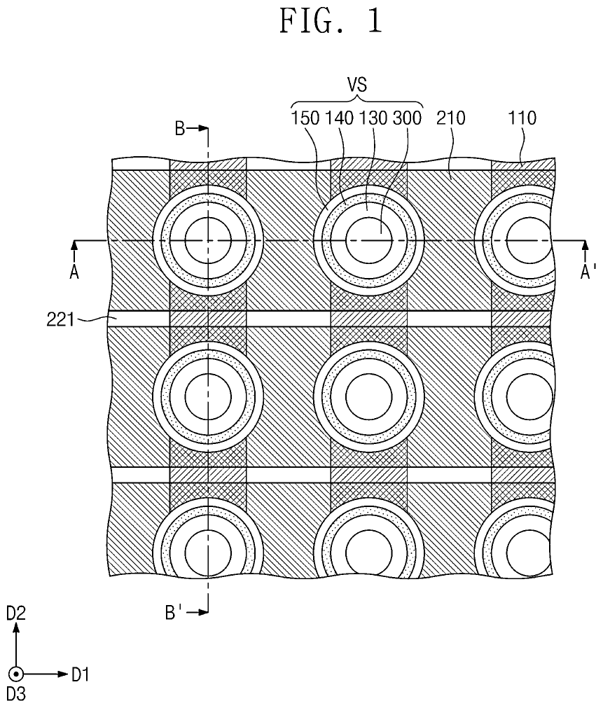

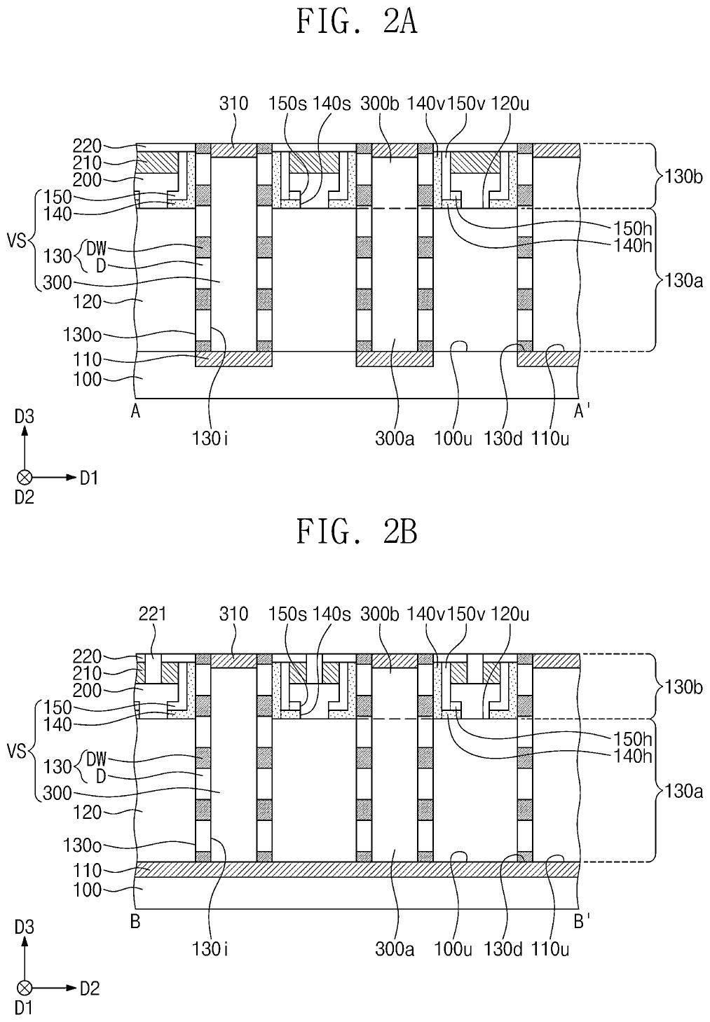

FIG. 1 illustrates a plan view showing a magnetic memory device according to some embodiments of the present inventive concepts. FIGS. 2A and 2B illustrate cross-sectional views showing a magnetic memory device according to some embodiments of the present inventive concepts. FIG. 2A illustrates a cross-sectional view taken along line A-A′ of FIG. 1. FIG. 2B illustrates a cross-sectional view taken along line B-B′ of FIG. 1.

Referring to FIGS. 1, 2A, and 2B, a substrate 100 may be provided therein with first wiring layers 110 that extend in a second direction D2 and are spaced apart from each other in a first direction D1 that intersects the second direction D2. The first direction D1 and the second direction D2 may be parallel to a top surface 100u of the substrate 100, and may be called a horizontal direction. A third direction D3 may be perpendicular to the top surface 100u of the substrate 100. For example, the first, second, and third directions D1, D2, and D3 may be orthogonal to each other. The top surface 100u of the substrate 100 may be coplanar with top surfaces 110u of the first wiring layers 110.

The substrate 100 may be a semiconductor substrate. The substrate 100 may be, for example, a silicon substrate, a germanium substrate, or a silicon-germanium substrate.

The first wiring layer 110 may include one or more of metal (e.g., copper, tungsten, or aluminum) and metal nitride (e.g., tantalum nitride, titanium nitride, or tungsten nitride).

A first dielectric pattern 120 may be on the substrate 100. A thickness in the third direction D3 of the first dielectric pattern 120 may be determined in proportion to the number of magnetic domains D of a free layer which will be discussed below. For example, the first dielectric pattern 120 may have a thickness that is equal to or less than about 5 μm.

The first dielectric pattern 120 may include, for example, one or more of silicon oxide, silicon nitride, and silicon oxynitride.

A vertical structure VS may penetrate or extend through the first dielectric pattern 120. The vertical structure VS may be provided in plural, and the plurality of vertical structures VS may be spaced apart from each other in the first direction D1 and the second direction D2. The vertical structures VS may have portions that penetrate the first dielectric pattern 120, and the portions of the vertical structures VS may be on the first wiring layer 110. A single vertical structure VS will be discussed below for brevity of description, but the following explanation may be applicable to other vertical structures VS.

The vertical structure VS may include a dielectric pillar 300 on the first wiring layer 110. The dielectric pillar 300 may include a penetration part 300a that penetrates or extends through the first dielectric pattern 120 and a protrusion part 300b that protrudes from a top surface 120u of the first dielectric pattern 120. A thickness in the third direction D3 of the protrusion part 300b may be determined in proportion to a size of a magnetic tunnel junction MTJ which will be discussed in greater below. For example, the protrusion part 300b may have a thickness of about 50 μm.

The dielectric pillar 300 may include, for example, one or more of silicon oxide, silicon nitride, and silicon oxynitride.

The vertical structure VS may include a first magnetic pattern 130 interposed between the first dielectric pattern 120 and the dielectric pillar 300. A bottom surface 130d of the first magnetic pattern 130 may be in contact with a top surface 110u of the first wiring layer 110. The first magnetic pattern 130 may include a first part 130a that surrounds a lateral surface of the penetration part 300a and a second part 130b that surrounds a lateral surface of the protrusion part 300b. The first magnetic pattern 130 may extend along the third direction D3. The first magnetic pattern 130 may have an outer sidewall 1300 and an inner sidewall 130i that have no undulation. The outer sidewall 1300 and the inner sidewall 130i of the first magnetic pattern 130 may each have a flat surface with no undulation.

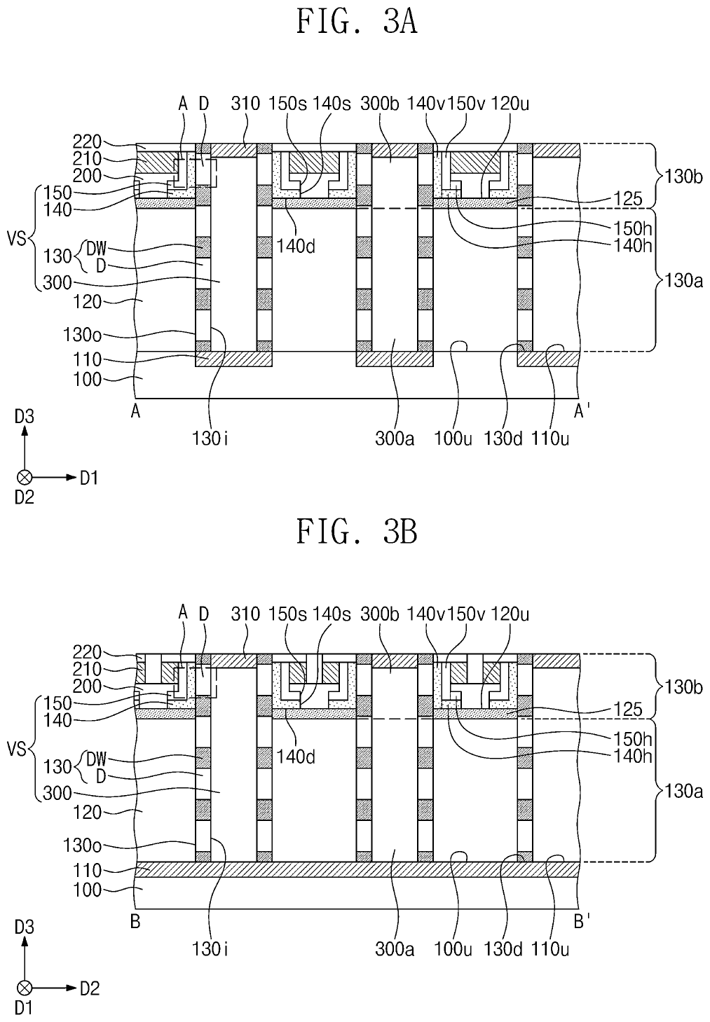

For example, as shown in FIGS. 2A to 3B, a diameter in the horizontal direction D1 or D2 of each of the outer sidewall 1300 and the inner sidewall 130i may be substantially constant in the third direction D3. The first magnetic pattern 130 may extend in a straight shape along the third direction D3.

Alternatively, although not shown, the diameter in the horizontal direction D1 or D2 of each of the outer sidewall 1300 and the inner sidewall 130i may increase in the third direction D3 at a constant rate.

The first magnetic pattern 130 may have no step difference in the third direction D3, and may surround and conform to the dielectric pillar 300.

The first magnetic pattern 130 may include a plurality of magnetic domains D and a plurality of magnetic domain walls DW. In the first magnetic pattern 130, the plurality of magnetic domains D and the plurality of magnetic domain walls DW may be arranged alternately and repeatedly along the third direction D3. The plurality of magnetic domains D may be regions whose magnetization directions are uniform in a magnetic substance (e.g., the first magnetic pattern 130), and the plurality of magnetic domain walls DW may be regions whose magnetization directions are changed between the plurality of magnetic domains D in the magnetic substance. Each of the plurality of magnetic domain walls DW may define a boundary between the magnetic domains D having different magnetization directions among the plurality of magnetic domains D. Sizes and magnetization directions of the magnetic domains D may be appropriately controlled by external energy and a shape and size of the magnetic substance. The magnetic domain walls DW may move by a current or magnetic field applied to the magnetic substance. Each of the first magnetic patterns 130 may include at least one selected from cobalt (Co), iron (Fe), and nickel (Ni).

The vertical structure VS may include a second magnetic pattern 150 that surrounds a lateral surface of the second part 130b of the first magnetic pattern 130. The second magnetic pattern 150 may be on the first dielectric pattern 120, and may not surround a lateral surface of the first part 130a of the first magnetic pattern 130. The second magnetic pattern 150 may include a vertical part 150v that extends along the vertical direction (e.g., the third direction D3) and a horizontal part 150h that protrudes from a lower portion of the vertical part 150v along the horizontal direction away from the dielectric pillar 300. The second magnetic pattern 150 may have an L shape when viewed in cross-section.

The vertical structure VS may include a tunnel barrier pattern 140 interposed between the second magnetic pattern 150 and the second part 130b of the first magnetic pattern 130. On the first dielectric pattern 120, the tunnel barrier pattern 140 may surround the lateral surface of the second part 130b of the first magnetic pattern 130. The tunnel barrier pattern 140 may not surround the lateral surface of the first part 130a of the first magnetic pattern 130. The tunnel barrier pattern 140 may include a vertical part 140v that extends along the vertical direction (e.g., the third direction D3) and a horizontal part 140h that protrudes from a lower portion of the vertical part 140v along the horizontal direction away from the dielectric pillar 300. The tunnel barrier pattern 140 may have an L shape when viewed in cross-section. The horizontal part 140h of the tunnel barrier pattern 140 may be interposed between the first dielectric pattern 120 and the horizontal part 150h of the second magnetic pattern 150. The vertical part 140v of the tunnel barrier pattern 140 may be interposed between the dielectric pillar 300 and the vertical part 150v of the second magnetic pattern 150.

A lateral surface 150s of the horizontal part 150h of the second magnetic pattern 150 may be aligned along the third direction D3 with a lateral surface 140s of the horizontal part 140h of the tunnel barrier pattern 140.

The tunnel barrier pattern 140 may include at least one selected from a magnesium (Mg) oxide layer, a titanium (Ti) oxide layer, an aluminum (Al) oxide layer, a magnesium-zinc (Mg—Zn) oxide layer, and/or a magnesium-boron (Mg—B) oxide layer.

On the first dielectric pattern 120, a second dielectric pattern 200 may be between a plurality of vertical structures VS. The second dielectric pattern 200 may be interposed between the second magnetic patterns 150 of the vertical structures VS. The second dielectric pattern 200 may extend onto the top surface 120u of the first dielectric pattern 120. The second dielectric pattern 200 may surround lower lateral surfaces of the second magnetic patterns 150. The second dielectric pattern 200 may cover the lateral surface 150s of the horizontal part 150h of the second magnetic pattern 150 and the lateral surface 140s of the horizontal part 140h of the tunnel barrier pattern 140. According to some embodiments, the second dielectric pattern 200 may be in contact with the top surface 120u of the first dielectric pattern 120.

The second dielectric pattern 200 may include, for example, one or more of silicon oxide, silicon nitride, and silicon oxynitride.

The second dielectric pattern 200 may be provided thereon with second wiring layers 210 that extend in the first direction D1 and are spaced apart from each other in the second direction D2. The second wiring layers 210 may be correspondingly between the second magnetic patterns 150 of the vertical structures VS that are spaced apart from each other in the first direction D1. Each of the second wiring layers 210 may surround upper lateral surfaces of the second magnetic patterns 150.

The second wiring layers 210 may include one or more of metal (e.g., copper, tungsten, or aluminum) and metal nitride (e.g., tantalum nitride, titanium nitride, or tungsten nitride).

An upper dielectric pattern 220 may cover a top surface of the tunnel barrier pattern 140, a top surface of the second magnetic pattern 150, and a top surface of the second wiring layer 210. A top surface of the upper dielectric pattern 220 may be substantially coplanar with an uppermost surface of the first magnetic pattern 130. When viewed in plan, the upper dielectric pattern 220 may entirely cover regions except uppermost surfaces of the first magnetic pattern 130 and the dielectric pillar 300 of the vertical structure VS.

The second wiring layers 210 may be provided therebetween with separation dielectric patterns 221 that extend in the first direction D1 and are spaced apart from each other in the second direction D2. The separation dielectric patterns 221 may penetrate the upper dielectric pattern 220. The separation dielectric patterns 221 may have their bottom surfaces in contact with a top surface of the second dielectric pattern 200. The separation dielectric patterns 221 may include, for example, one or more of silicon oxide, silicon nitride, and silicon oxynitride.

A third wiring layer 310 may be on the dielectric pillar 300. When viewed in a plan view, the dielectric pillar 300 and the third wiring layer 310 may overlap each other. The second part 130b of the first magnetic pattern 130 may extend higher in the third direction D3 than a top surface of the dielectric pillar 300. Stated differently, an upper portion of the second part 130b of the first magnetic pattern 130 may be farther from the top surface 100u of the substrate 100 than the top surface of the dielectric pillar 300 is from the top surface 100u of the substrate 100. On the dielectric pillar 300, the third wiring layer 310 may be in contact with the inner sidewall 130i of the first magnetic pattern 130.

The third wiring layer 310 may include one or more of metal (e.g., copper, tungsten, or aluminum) and metal nitride (e.g., tantalum nitride, titanium nitride, or tungsten nitride).

FIGS. 3A and 3B illustrate cross-sectional views showing a magnetic memory device according to some embodiments of the present inventive concepts. FIG. 3A illustrates a cross-sectional view taken along line A-A′ of FIG. 1. FIG. 3B illustrates a cross-sectional view taken along line B-B′ of FIG. 1. For brevity of description, a repetitive explanation will be omitted.

Referring to FIGS. 3A and 3B, an etch stop layer 125 may be interposed between the first dielectric pattern 120 and a bottom surface 140d of the tunnel barrier pattern 140. For example, the etch stop layer 125 may be interposed between the first dielectric pattern 120 and the horizontal part 140h of the tunnel barrier pattern 140. The etch stop layer 125 may extend onto the top surface 120u of the first dielectric pattern 120 and may contact the outer sidewall 1300 of the first magnetic pattern 130. When viewed in a plan view, the etch stop layer 125 may overlap the first dielectric pattern 120. For example, the etch stop layer 125 may overlap vertically (or in the third direction D3) with the first dielectric pattern 120.

On the etch stop layer 125, a second dielectric pattern 200 may be between a plurality of vertical structures VS. The second dielectric pattern 200 may be interposed between the second magnetic patterns 150 of the vertical structures VS. The second dielectric pattern 200 may extend onto and contact a top surface of the etch stop layer 125.

The etch stop layer 125 may include a material having an etch selectivity with respect to one or more of silicon oxide, silicon nitride, and silicon oxynitride. The etch stop layer 125 may include metal oxide, such as at least one selected from hafnium oxide (HfO₂) and aluminum oxide (Al₂O₃).

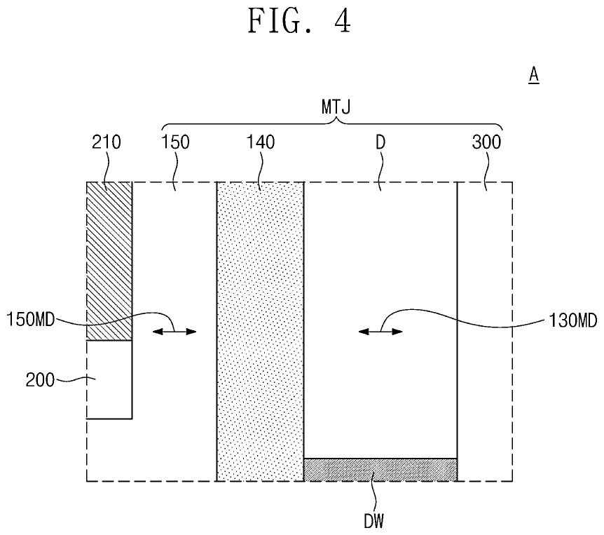

FIG. 4 illustrates an enlarged view showing section A of FIGS. 3A and 3B. For brevity of description, a repetitive explanation will be omitted.

Referring to FIGS. 3A, 3B, and 4, the second magnetic pattern 150 may be a reference layer having a magnetization direction 150MD that is fixed in one direction, and the first magnetic pattern 130 may be a free layer having a magnetization direction 130MD that is changed. Each of the magnetic domains D may have a magnetization direction 130MD that is changed to be parallel or antiparallel to the magnetization direction 150MD of the second magnetic pattern 150. For example, referring to FIG. 4, the magnetization direction 150MD of the second magnetic pattern 150 and the magnetization direction 130MD of each of the magnetic domains D may be perpendicular to an interface between the tunnel barrier pattern 140 and the second magnetic pattern 150. In this case, each of the second magnetic pattern 150 and the first magnetic pattern 130 may include at least one selected from a perpendicular magnetic material (e.g., CoFeTb, CoFeGd, CoFeDy), a perpendicular magnetic material having an L10 structure, CoPt of a hexagonal close packed (HCP) lattice structure, and a perpendicular magnetic structure. The perpendicular magnetic material having the L10 structure may include at least one selected from FePt of the L10 structure, FePd of the L10 structure, CoPd of the L10 structure, and CoPt of the L10 structure. The perpendicular magnetic structure may include magnetic layers and non-magnetic layers that are alternately and repeatedly stacked. For example, the perpendicular magnetic structure may include at least one selected from (Co/Pt)n, (CoFe/Pt)n, (CoFe/Pd)n, (Co/Pd)n, (Co/Ni)n, (CoNi/Pt)n, (CoCr/Pt)n, and (CoCr/Pd)n (where, n is the number of stacked layers). Alternatively, although not shown, the magnetization direction 150MD of the second magnetic pattern 150 and the magnetization direction 130MD of each of magnetic domains D may be parallel to the interface between the tunnel barrier pattern 140 and the second magnetic pattern 150. In this case, the second magnetic pattern 150 and the first magnetic pattern 130 may include a ferromagnetic material, and the second magnetic pattern 150 may further include an antiferromagnetic material for fixing a magnetization direction of the ferromagnetic material. A magnetic tunnel junction MTJ may be constituted by each of the magnetic domains D of the first magnetic pattern 130, the second magnetic pattern 150, and the tunnel barrier pattern 140.

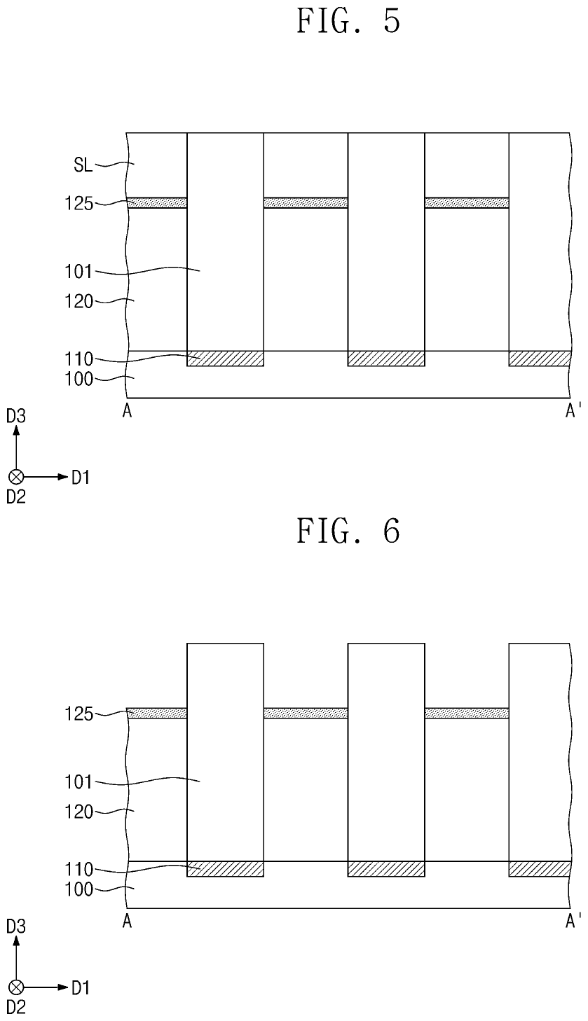

FIGS. 5 to 14 illustrate cross-sectional views showing a method of fabricating a magnetic memory device depicted in FIGS. 3A and 3B. FIGS. 5 to 11, 13, and 14 illustrate cross-sectional views taken along line A-A′ of FIG. 1. FIG. 12 illustrates a cross-sectional view taken along line B-B′ of FIG. 1. Omission will be made to avoid a repetitive explanation discussed with reference to FIGS. 1 to 3B.

Referring to FIGS. 3A, 3B, and 5, first wiring layers 110 may be formed on a substrate 100 which may extend in a second direction D2 and are spaced apart from each other in a first direction D1 that intersects the second direction D2. The formation of the first wiring layers 110 may include forming a mask layer (not shown) on the substrate 100, patterning the mask layer to form a mask pattern (not shown), using the mask pattern as an etching mask to etch the substrate 100 to form a recessed portion, depositing the first wiring layers 110 on the recessed portion, and removing the mask pattern.

A first dielectric pattern 120 may be formed on the substrate 100. The first dielectric pattern 120 may be formed by using chemical vapor deposition (CVD) or physical vapor deposition (PVD) such as sputtering deposition.

An etch stop layer 125 may be formed on the first dielectric pattern 120. A sacrificial layer SL may be formed on the etch stop layer 125. The sacrificial layer SL may include the same material as that of the first dielectric pattern 120.

A sacrificial pillar 101 may be formed to penetrate or extend through the sacrificial layer SL, the etch stop layer 125, and the first dielectric pattern 120. The sacrificial pillar 101 may be provided in plural, and the plurality of sacrificial pillars 101 may be spaced apart from each other in the first direction D1 and the second direction D2. The sacrificial pillars 101 may be on the first wiring layer 110. The formation of the sacrificial pillars 101 may include forming a mask layer (not shown) on the sacrificial layer SL, patterning the mask layer to form a mask pattern (not shown), using the mask pattern as an etching mask to form holes that penetrate the sacrificial layer SL, the etch stop layer 125, and the first dielectric pattern 120, depositing the sacrificial pillars 101 in the holes, and removing the mask pattern. The sacrificial pillars 101 may include a material having an etch selectivity with respect to the first dielectric pattern 120. For example, when the first dielectric pattern 120 includes silicon oxide, the sacrificial pillars 101 may include silicon nitride.

Referring to FIGS. 3A, 3B, and 6, the sacrificial layer SL may be removed. The sacrificial layer SL may be removed by a wet etching process. During the removal of the sacrificial layer SL, the sacrificial pillars 101 and the etch stop layer 125 may not be removed due to their etch selectivity.

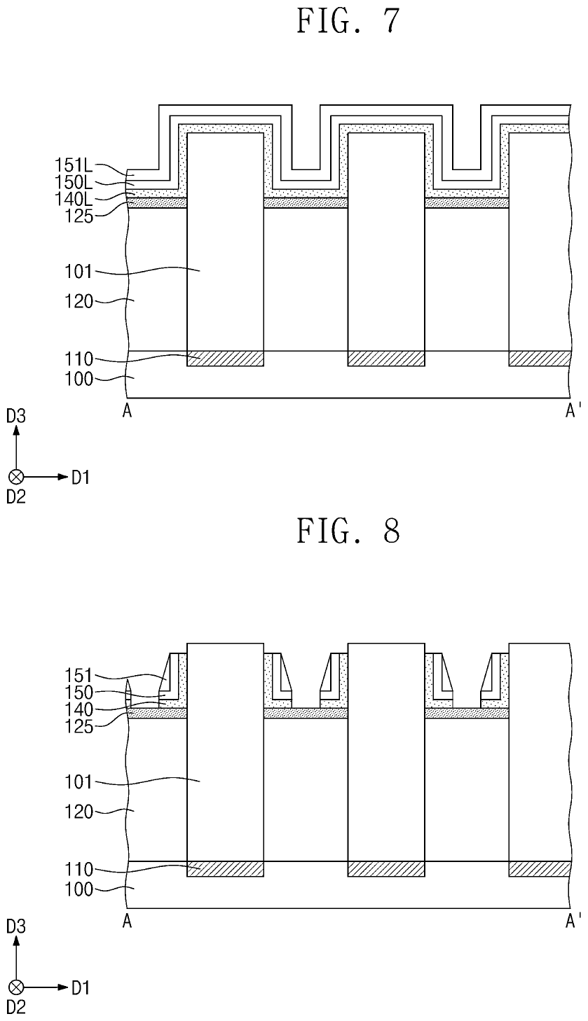

Referring to FIGS. 3A, 3B, and 7, a tunnel barrier layer 140L, a second magnetic layer 150L, and a capping layer 151L may be sequentially formed. The tunnel barrier layer 140L, the second magnetic layer 150L, and the capping layer 151L may extend onto the etch stop layer 125, while conforming to and covering upper lateral surfaces and top surfaces of the sacrificial pillars 101. The tunnel barrier layer 140L, the second magnetic layer 150L, and the capping layer 151L may be sequentially deposited by using at least one selected from chemical vapor deposition (CVD), physical vapor deposition (PVD), and atomic layer deposition (ALD).

The capping layer 151L may include a material having an etch selectivity with respect to the etch stop layer 125 and the sacrificial pillars 101. For example, when the sacrificial pillars 101 include silicon oxide, the capping layer 151L may include silicon nitride.

Referring to FIGS. 3A, 3B, and 8, there may be formed a tunnel barrier pattern 140, a second magnetic pattern 150, and a capping pattern 151. The tunnel barrier pattern 140, the second magnetic pattern 150, and the capping pattern 151 may be formed by an anisotropic etching process. The anisotropic etching process may cause the second magnetic pattern 150 to include a vertical part 150v that extends along a vertical direction (e.g., a third direction D3) and a horizontal part 150h that protrudes from a lower portion of the vertical part 150v along a horizontal direction away from the sacrificial pillar 101. In addition, the tunnel barrier pattern 140 may include a vertical part 140v that extends along the vertical direction (e.g., the third direction D3) and a horizontal part 140h that protrudes from a lower portion of the vertical part 140v along the horizontal direction away from the sacrificial pillar 101 The second magnetic pattern 150 and the tunnel barrier pattern 140 may each have an L shape when viewed in cross-section. The capping pattern 151 may be formed on a lateral surface of the second magnetic pattern 150.

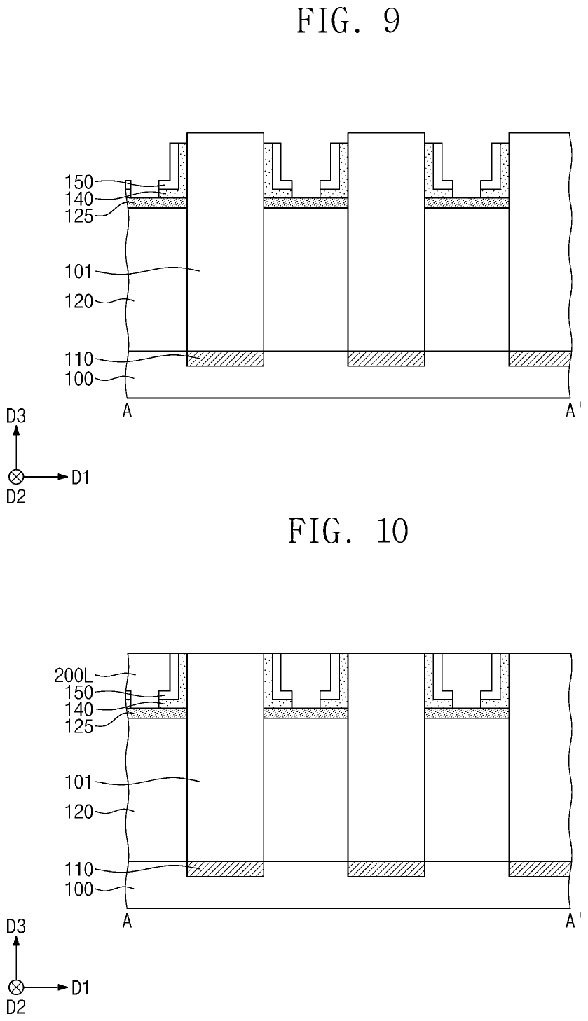

Referring to FIGS. 3A, 3B, and 9, the capping pattern 151 may be removed. A wet etching process may be performed to remove the capping pattern 151. In the etching process that removes the capping pattern 151, neither the etch stop layer 125 nor the sacrificial pillars 101 may be etched.

Referring to FIGS. 3A, 3B, and 10, a second dielectric layer 200L may be formed between the second magnetic patterns 150. The second dielectric layer 200L may extend onto a top surface of the etch stop layer 125. The formation of the second dielectric layer 200L may include forming a dielectric layer (not shown) that covers the lateral surface of the second magnetic pattern 150 and the top surface of the sacrificial pillar 101, and removing an upper portion of the dielectric layer to form the second dielectric layer 200L. A planarization process may be performed to remove the upper portion of the dielectric layer. The planarization process may include, for example, a chemical mechanical polishing (CMP) process or an etch-back process. During the planarization process, an upper portion of the sacrificial pillar 101 may be removed. Therefore, a top surface of the sacrificial pillar 101 may be substantially coplanar with a top surface of the second dielectric layer 200L, a top surface of the second magnetic pattern 150, and a top surface of the tunnel barrier pattern 140.

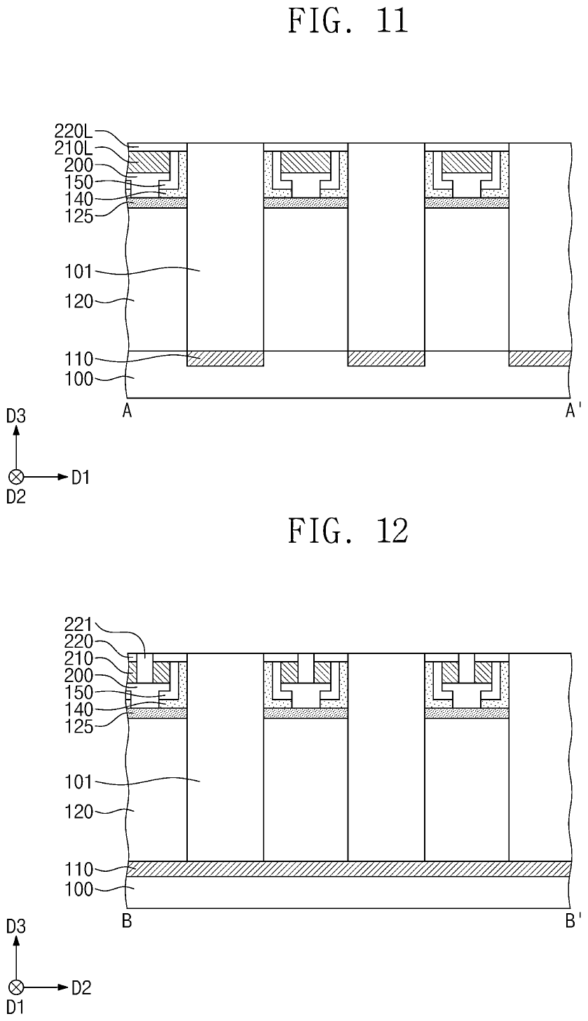

Referring to FIGS. 3A, 3B, and 11, an upper portion of the second dielectric layer 200L may be recessed to form a second dielectric pattern 200. An etching process may be performed to form the second dielectric pattern 200. A top surface of the second dielectric pattern 200 may be located at a lower height than that of an uppermost surface of the second magnetic pattern 150 and that of an uppermost surface of the tunnel barrier pattern 140.

A second wiring material layer 210L may be formed in (e.g., may fill) a recessed upper portion of the second dielectric layer 200L. For example, the second wiring material layer 210L may be formed on the second dielectric pattern 200. A top surface of the second wiring material layer 210L may be substantially coplanar with the uppermost surface of the second magnetic pattern 150 and the uppermost surface of the tunnel barrier pattern 140.

An upper dielectric layer 220L may be formed on the second wiring material layer 210L. The upper dielectric layer 220L may cover the top surface of the second wiring material layer 210L, the top surface of the second magnetic pattern 150, and the top surface of the tunnel barrier pattern 140. A top surface of the upper dielectric layer 220L may be substantially coplanar with that of the sacrificial pillar 101. The formation of the upper dielectric layer 220L may include forming a dielectric layer (not shown) that covers the second wiring material layer 210L, the second magnetic pattern 150, the tunnel barrier pattern 140, and the sacrificial pillar 101, and then performing a planarization process on the dielectric layer. The dielectric layer may be formed by chemical vapor deposition (CVD) or physical vapor deposition (PVD) such as sputtering deposition. The planarization process may continue until the top surface of the sacrificial pillar 101 is exposed, thereby forming the upper dielectric layer 220L.

Referring to FIGS. 3A, 3B, and 12, a separation dielectric pattern 221 may be formed to penetrate or extend through the upper dielectric layer 220L and the second wiring material layer 210L. The separation dielectric pattern 221 may be formed in plural, and the plurality of separation dielectric patterns 221 may extend in the first direction D1 and may be spaced apart from each other in the second direction D2. The formation of the separation dielectric pattern 221 may include forming a mask layer (not shown) on the upper dielectric layer 220L and the sacrificial pillar 101, patterning the mask layer to form a mask pattern (not shown), using the mask pattern as an etching mask to etch the upper dielectric layer 220L and the second wiring material layer 210L, forming a separation dielectric layer (not shown) to fill an etched portion of the upper dielectric layer 220L and the second wiring material layer 210L, removing the mask pattern, and performing a planarization process. A bottom surface of the separation dielectric pattern 221 may be in contact with the top surface of the second dielectric pattern 200.

The separation dielectric pattern 221 may separate the second wiring material layer 210L into a plurality of second wiring layers 210. The second wiring layers 210 may extend in the first direction D1 and may be spaced apart from each other in the second direction D2. In addition, the separation dielectric pattern 221 may separate the upper dielectric layer 220L into an upper dielectric pattern 220.

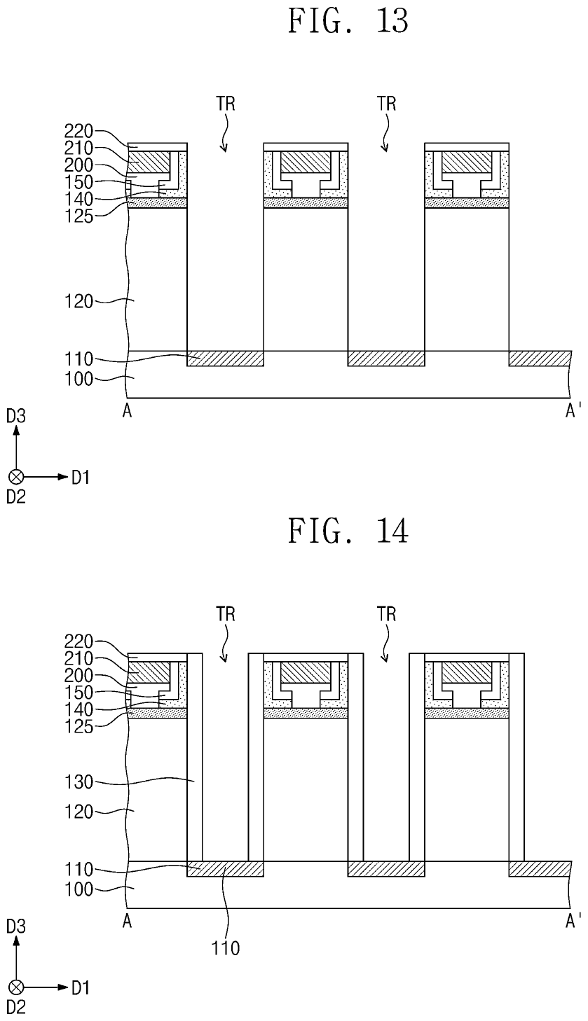

Referring to FIGS. 3A, 3B, and 13, the sacrificial pillar 101 may be removed to form a trench TR. The trench TR may be formed by a wet etching process.

Referring to FIGS. 3A, 3B, and 14, a first magnetic pattern 130 may be formed. The first magnetic pattern 130 may cover and conform to a sidewall of the trench TR. The formation of the first magnetic pattern 130 may include depositing a first magnetic layer (not shown) and removing a portion of the first magnetic layer in contact with the first wiring layer 110 and a portion of the first magnetic layer formed on the upper dielectric pattern 220. The first magnetic layer may be formed by using a film formation technique whose step coverage is relatively good excellent, such as chemical vapor deposition (CVD) or atomic layer deposition (ALD). The first magnetic layer may include a plurality of magnetic domains D and a plurality of magnetic domain walls DW. An anisotropic etching process may be performed to remove the portion of the first magnetic layer in contact with the first wiring layer 110 and the portion of the first magnetic layer formed on the upper dielectric pattern 220.

Referring back to FIGS. 3A and 3B, a dielectric pillar 300 may be formed in an unoccupied portion of the trench TR filled with the first magnetic pattern 130. A technique such as chemical vapor deposition (CVD) or physical vapor deposition (PVD) may be used to form the dielectric pillar 300.

A third wiring layer 310 may be formed on the dielectric pillar 300. The third wiring layer 310 may be formed by recessing an upper portion of the dielectric pillar 300, and filling the recessed portion with the third wiring layer 310.

According to some embodiments, the formation of the etch stop layer 125 may be omitted, and in this case, as shown in FIGS. 2A and 2B, the second dielectric pattern 200 may be in contact with the first dielectric pattern 120.

A magnetic memory device that uses the motion of a magnetic domain wall of a magnetic material may have a structure in which a free layer, a barrier layer, and a pinned layer are sequentially stacked. However, in this case, an elaborate process control may be needed in patterning the free layer, the barrier layer, and the pinned layer. In addition, etching-induced contamination may occur at an interface of the free or barrier layer.

According to the present inventive concepts, the first magnetic pattern 130 that corresponds to the free layer may be formed to have a vertical shape. Moreover, the magnetic tunnel junction MTJ may be formed by forming the tunnel barrier pattern 140 and the second magnetic pattern 150 on a sidewall of the first magnetic pattern 130. In this case, differently from the case that forms a structure in which the free layer, the barrier layer, and the pinned layer are sequentially stacked, it may be possible to suppress etching-induced contamination at an interface between the first magnetic pattern 130 and the tunnel barrier pattern 140. It may thus be possible to decrease difficulty in fabricating a magnetic memory device. Therefore, the magnetic memory device may be more easily mass-fabricated. Further, the first magnetic pattern 130 may be formed to have the outer sidewall 1300 and the inner sidewall 130i that have no undulation. As no undulation is present, there may be an increase in moving speeds of the magnetic domain walls DW and easiness in accurate position control of the magnetic domains D. Accordingly, a magnetic memory device may have improved electrical properties and increased reliability.

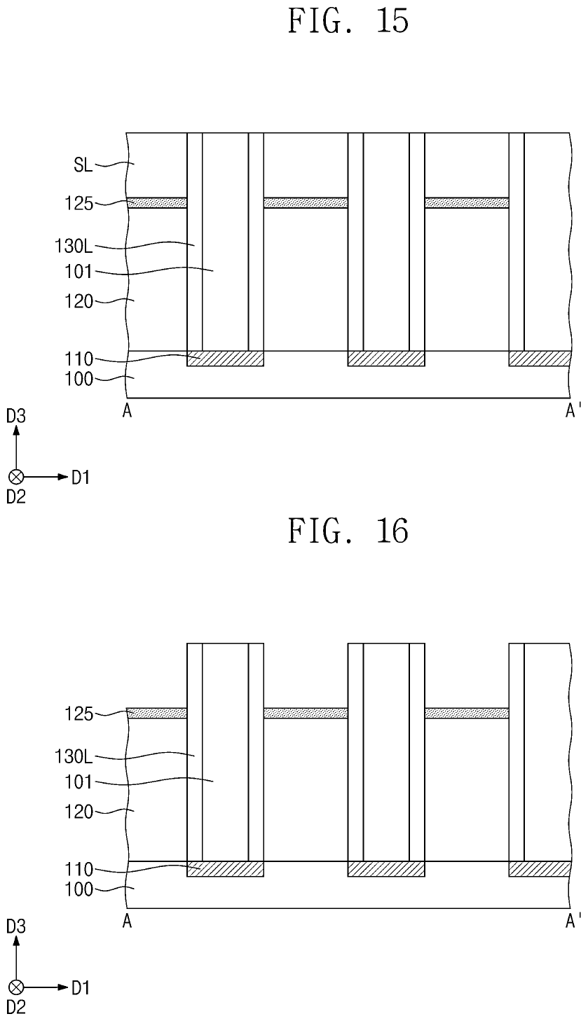

FIGS. 15 to 18 illustrate cross-sectional views showing a method of fabricating a magnetic memory device depicted in FIGS. 3A and 3B. For brevity of description, some repetitive explanation will be omitted.

Referring to FIGS. 3A, 3B, and 15, a first magnetic layer 130L may be formed to surround the sacrificial pillar 101. The first magnetic layer 130L may be interposed between the first dielectric pattern 120 and the sacrificial pillar 101. The first magnetic layer 130L may extend between the sacrificial pillar 101 and a lateral surface of each of the etch stop layer 125 and the sacrificial layer SL. The formation of the first magnetic layer 130L may include forming a mask layer (not shown) on the sacrificial layer SL, patterning the mask layer to form a mask pattern (not shown), using the mask pattern as an etching mask to form holes that penetrate the sacrificial layer SL, the etch stop layer 125, and the first dielectric pattern 120, removing the mask pattern, depositing the first magnetic layer 130L to conformally cover sidewalls of the holes, and removing a portion of the first magnetic layer 130L in contact with an upper portion of the sacrificial layer SL and a portion of the first magnetic layer 130L in contact with the first wiring layer 110. The first magnetic layer 130L may include a plurality of magnetic domains D and a plurality of magnetic domain walls DW. The formation of the sacrificial pillar 101 may include allowing the sacrificial pillar 101 to fill an unoccupied portion of the hole filled with the first magnetic layer 130L.

Referring to FIGS. 3A, 3B, and 16, the sacrificial layer SL may be removed. The sacrificial layer SL may be removed by a wet etching process. During the removal of the sacrificial layer SL, the sacrificial pillars 101, the first magnetic layer 130L, and the etch stop layer 125 may not be removed due to their etch selectivity.

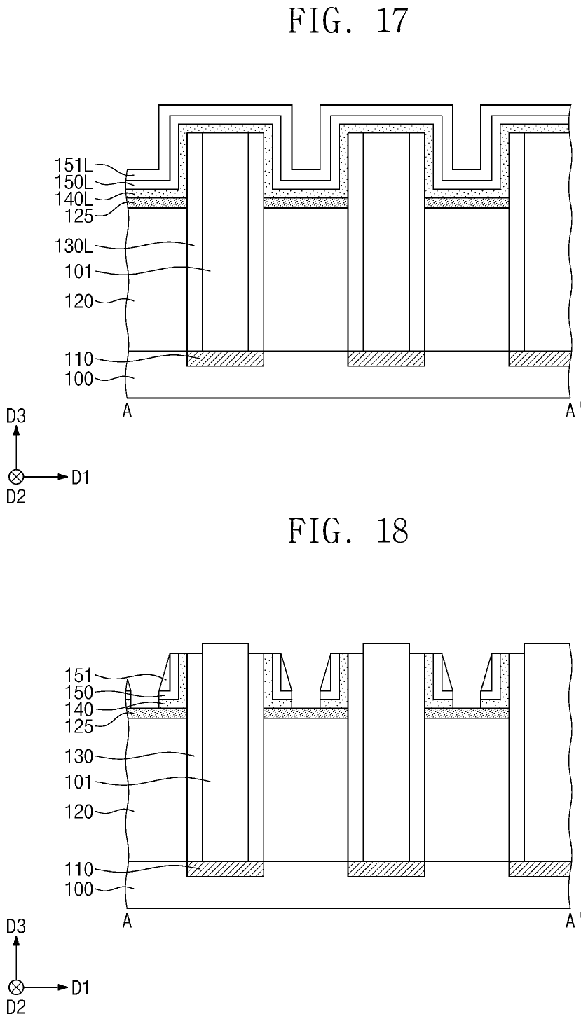

Referring to FIGS. 3A, 3B, and 17, a tunnel barrier layer 140L, a second magnetic layer 150L, and a capping layer 151L may be sequentially formed. The tunnel barrier layer 140L, the second magnetic layer 150L, and the capping layer 151L may extend onto the etch stop layer 125, while covering and conforming to lateral and top surfaces of the first magnetic layer 130L and the top surface of the sacrificial pillar 101.

Referring to FIGS. 3A, 3B, and 18, a tunnel barrier pattern 140, a second magnetic pattern 150, and a capping pattern 151 may be formed. The tunnel barrier pattern 140, the second magnetic pattern 150, and the capping pattern 151 may be formed by an anisotropic etching process. The anisotropic etching process may cause the second magnetic pattern 150 to include a vertical part 150v that extends along the vertical direction (e.g., the third direction D3) and a horizontal part 150h that protrudes from a lower portion of the vertical part 150v along the horizontal direction away from the sacrificial pillar 101. The second magnetic pattern 150 may have an L shape when viewed in cross-section. In addition, the tunnel barrier pattern 140 may include a vertical part 140v that extends along the vertical direction (e.g., the third direction D3) and a horizontal part 140h that protrudes from a lower portion of the vertical part 140v along the horizontal direction away from the sacrificial pillar 101 The tunnel barrier pattern 140 may have an L shape when viewed in cross-section. The capping pattern 151 may be formed on a lateral surface of the second magnetic pattern 150. In the anisotropic etching process, a first magnetic pattern 130 may be formed. An upper portion of the first magnetic layer 130L may be partially removed to form the first magnetic pattern 130. A top surface of the second magnetic pattern 150 may be substantially coplanar with that of the tunnel barrier pattern 140 and that of the first magnetic pattern 130.

Subsequently, substantially the same process as that discussed with reference to FIGS. 9 to 14 may be employed to fabricate a magnetic memory device of FIGS. 3A and 3B. When the process of FIGS. 15 to 17 is used for fabrication, the tunnel barrier pattern 140 may have reduced contamination. For example, in the procedure discussed with FIG. 13, when the sacrificial pillar 101 is removed by a wet etching process to form the trench TR, the tunnel barrier pattern 140 may be exposed to an etching solution of the wet etching process. When the etching solution includes water, the tunnel barrier pattern 140 may suffer from a problem of swelling. According to the present inventive concepts, when the process of FIGS. 15 to 17 is used for fabrication, the tunnel barrier pattern 140 may be prevented from being in contact with the etching solution. This may be caused by the fact that the first magnetic layer 130L is already formed on a lateral surface of the tunnel barrier pattern 140. Accordingly, a magnetic memory device may have improved electrical properties and increased reliability.

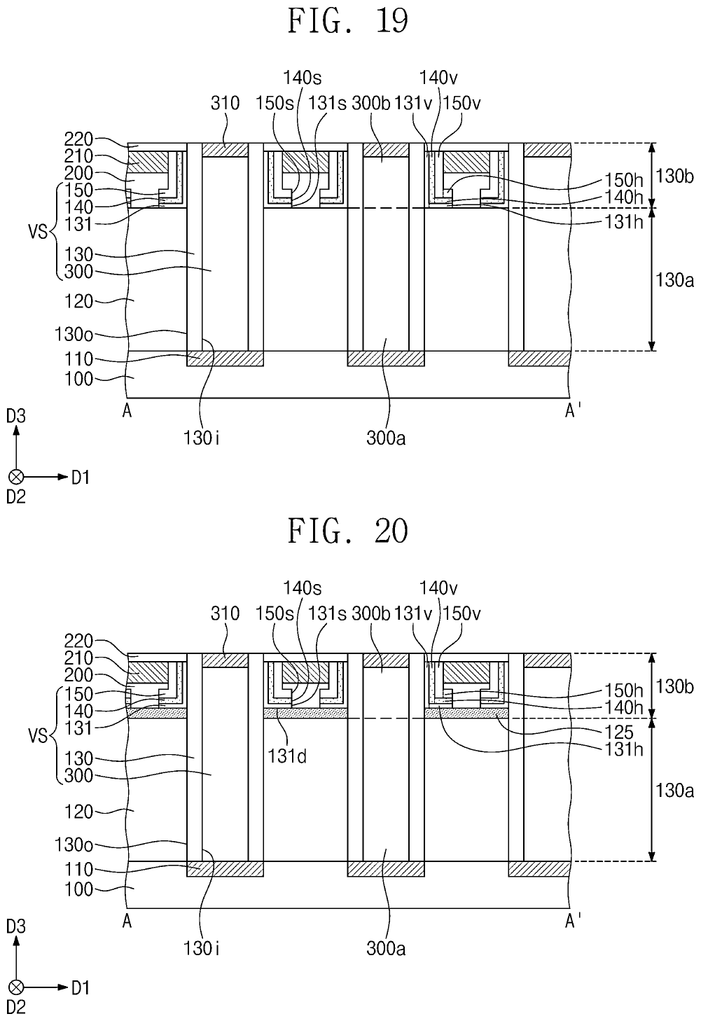

FIGS. 19 and 20 illustrate cross-sectional views showing a magnetic memory device according to some embodiments of the present inventive concepts. For brevity of description, a repetitive explanation will be omitted.

Referring to FIGS. 1 and 19, according to some embodiments, the vertical structure VS may include a dielectric pillar 300, a first magnetic pattern 130, a tunnel barrier pattern 140, a second magnetic pattern 150, and a first sub-magnetic pattern 131. The dielectric pillar 300, the first magnetic pattern 130, the tunnel barrier pattern 140, and the second magnetic pattern 150 may be substantially the same as those discussed with reference to FIGS. 2A to 3B.

The first sub-magnetic pattern 131 may be interposed between the tunnel barrier pattern 140 and the first magnetic pattern 130. The first sub-magnetic pattern 131 may surround the second part 130b of the first magnetic pattern 130. The first sub-magnetic pattern 131 may be disposed on the first dielectric pattern 120, and may not surround the first part 130a of the first magnetic pattern 130. The first sub-magnetic pattern 131 may include a vertical part 131v that extends along the vertical direction (e.g., the third direction D3) and a horizontal part 131h that protrudes from a lower portion of the vertical part 131v along the horizontal direction away from the dielectric pillar 300. The horizontal part 131h of the first sub-magnetic pattern 131 may be interposed between the first dielectric pattern 120 and the horizontal part 140h of the tunnel barrier pattern 140. The vertical part 131v of the first sub-magnetic pattern 131 may be interposed between the dielectric pillar 300 and the vertical part 140v of the tunnel barrier pattern 140.

A lateral surface 150s of the horizontal part 150h of the second magnetic pattern 150 may be aligned along the third direction D3 with a lateral surface 140s of the horizontal part 140h of the tunnel barrier pattern 140 and a lateral surface 131s of the horizontal part 131h of the first sub-magnetic pattern 131.

The first sub-magnetic pattern 131 may include substantially the same material as that of the first magnetic pattern 130.

On the first dielectric pattern 120, a second dielectric pattern 200 may be disposed between a plurality of vertical structures VS. The second dielectric pattern 200 may be interposed between the second magnetic patterns 150 of each of the vertical structures VS. The second dielectric pattern 200 may extend onto the top surface 120u of the first dielectric pattern 120. The second dielectric pattern 200 may surround lower lateral surfaces of the second magnetic patterns 150. The second dielectric pattern 200 may cover the lateral surface 150s of the horizontal part 150h of the second magnetic pattern 150, the lateral surface 140s of the horizontal part 140h of the tunnel barrier pattern 140, and the lateral surface 131s of the horizontal part 131h of the first sub-magnetic pattern 131.

Referring to FIGS. 1 and 20, according to some embodiments, an etch stop layer 125 may be interposed between the first dielectric pattern 120 and a bottom surface 131d of the first sub-magnetic pattern 131. For example, the etch stop layer 125 may be interposed between the first dielectric pattern 120 and the horizontal part 131h of the first sub-magnetic pattern 131. The etch stop layer 125 may extend onto the top surface 120u of the first dielectric pattern 120 and may contact the outer sidewall 1300 of the first magnetic pattern 130. When viewed in plan, the etch stop layer 125 may overlap the first dielectric pattern 120.

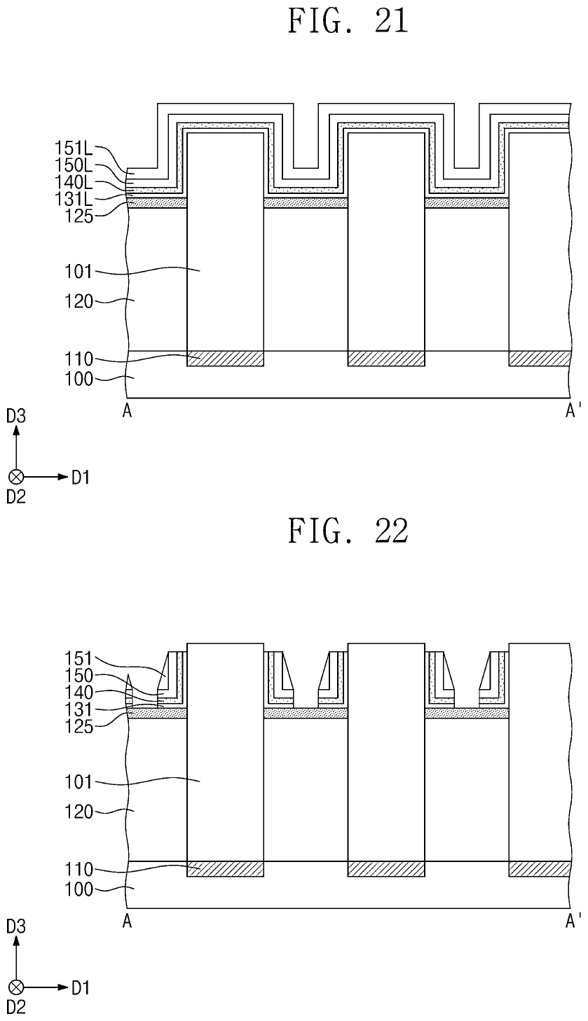

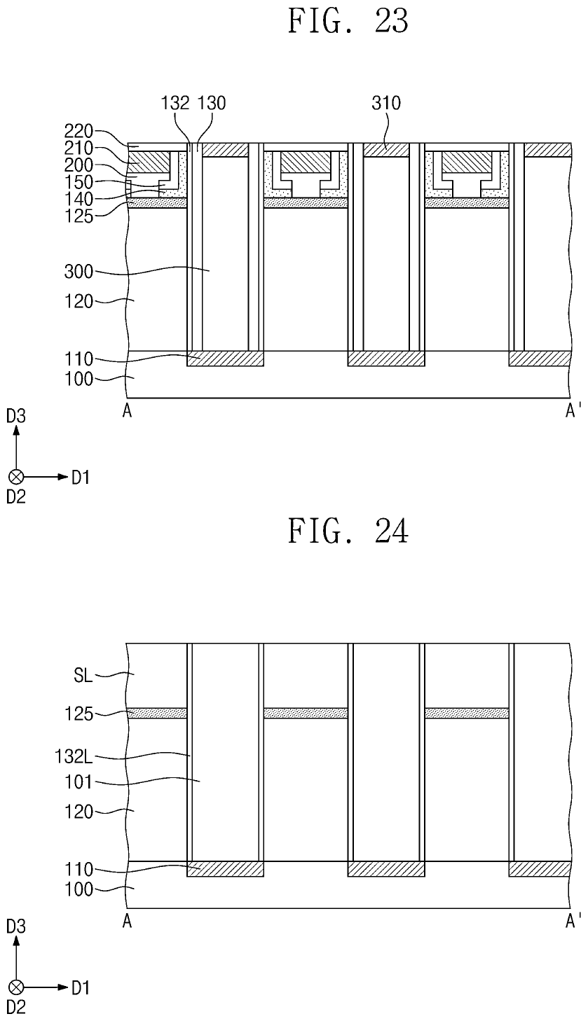

FIGS. 21 and 22 illustrate cross-sectional views showing a method of fabricating a magnetic memory device depicted in FIG. 20. For brevity of description, a some repetitive explanation will be omitted.

Referring to FIG. 21, a first sub-magnetic layer 131L, a tunnel barrier layer 140L, a second magnetic layer 150L, and a capping layer 151L may be sequentially formed. The first sub-magnetic layer 131L, the tunnel barrier layer 140L, the second magnetic layer 150L, and the capping layer 151L may extend onto the etch stop layer 125, while covering and conforming to lateral and top surfaces of the sacrificial pillar 101. The first sub-magnetic layer 131L, the tunnel barrier layer 140L, the second magnetic layer 150L, and the capping layer 151L may be sequentially deposited by using at least one selected from chemical vapor deposition (CVD), physical vapor deposition (PVD), and atomic layer deposition (ALD).

Referring to FIGS. 20 and 22, there may be formed a first sub-magnetic pattern 131, a tunnel barrier pattern 140, a second magnetic pattern 150, and a capping pattern 151. An anisotropic etching process may be performed to form the first sub-magnetic pattern 131, the tunnel barrier pattern 140, the second magnetic pattern 150, and the capping pattern 151. The anisotropic etching process may cause the second magnetic pattern 150 to include a vertical part 150v and a horizontal part 150h that protrudes from a lower portion of the vertical part 150v along the horizontal direction away from the sacrificial pillar 101. The tunnel barrier pattern 140 may include a vertical part 140v and a horizontal part 140h that protrudes from a lower portion of the vertical part 140v along the horizontal direction away from the sacrificial pillar 101. In addition, the first sub-magnetic pattern 131 may include a vertical part 131v and a horizontal part 131h that protrudes from a lower portion of the vertical part 131v along the horizontal direction away from the sacrificial pillar 101. The capping pattern 151 may be formed on a lateral surface of the second magnetic pattern 150.

Subsequently, a magnetic memory device of FIG. 20 may be fabricated through a process substantially the same as that discussed with reference to FIGS. 9 to 14. When a magnetic memory device is fabricated as shown in FIGS. 19 and 20, the tunnel barrier pattern 140 may have reduced contamination. For example, in the procedure discussed with FIG. 13, when the sacrificial pillar 101 is removed by a wet etching process to form the trench TR, the tunnel barrier pattern 140 may be exposed to an etching solution of the wet etching process. When the etching solution includes water, the tunnel barrier pattern 140 may suffer from a problem of swelling. According to the present inventive concepts, when the process of FIGS. 20 to 21 is used for fabrication, the tunnel barrier pattern 140 may be prevented from being in contact with the etching solution. This may be caused by the fact that the first sub-magnetic pattern 131 is already formed on a lateral surface of the tunnel barrier pattern 140. Accordingly, a magnetic memory device may have improved electrical properties and increased reliability.

FIG. 23 illustrates a cross-sectional view showing a magnetic memory device according to some embodiments of the present inventive concepts. FIGS. 24 to 27 illustrate cross-sectional views showing a method of fabricating a magnetic memory device depicted in FIG. 23. For brevity of description, a repetitive explanation will be omitted.

Referring to FIG. 23, a second sub-magnetic pattern 132 may surround the first magnetic pattern 130. The second sub-magnetic pattern 132 may be interposed between the first magnetic pattern 130 and the first dielectric pattern 120. The second sub-magnetic pattern 132 may extend in the third direction D3. The second sub-magnetic pattern 132 may include substantially the same material as that of the first magnetic pattern 130. The second sub-magnetic pattern 132 together with the first magnetic pattern 130 may be a free layer having a changeable magnetization direction.

Referring to FIG. 24, a second sub-magnetic layer 132L may be formed to surround the sacrificial pillar 101. The second sub-magnetic layer 132L may be interposed between the first dielectric pattern 120 and the sacrificial pillar 101. The second sub-magnetic layer 132L may extend between the sacrificial pillar 101 and a lateral surface of each of the etch stop layer 125 and the sacrificial layer SL. The formation of the second sub-magnetic layer 132L may include forming a mask layer (not shown) on the sacrificial layer SL, patterning the mask layer to form a mask pattern (not shown), using the mask pattern as an etching mask to form holes that penetrate the sacrificial layer SL, the etch stop layer 125, and the first dielectric pattern 120, removing the mask pattern, depositing the second sub-magnetic layer 132L to conformally cover sidewalls of the holes, and removing a portion of the second sub-magnetic layer 132L in contact with an upper portion of the sacrificial layer SL and a portion of the second sub-magnetic layer 132L in contact with the first wiring layer 110. The second sub-magnetic layer 132L may include a plurality of magnetic domains D and a plurality of magnetic domain walls DW. The formation of the sacrificial pillar 101 may include allowing the sacrificial pillar 101 to be in (e.g., fill) an unoccupied portion of the hole filled with the second sub-magnetic layer 132L.

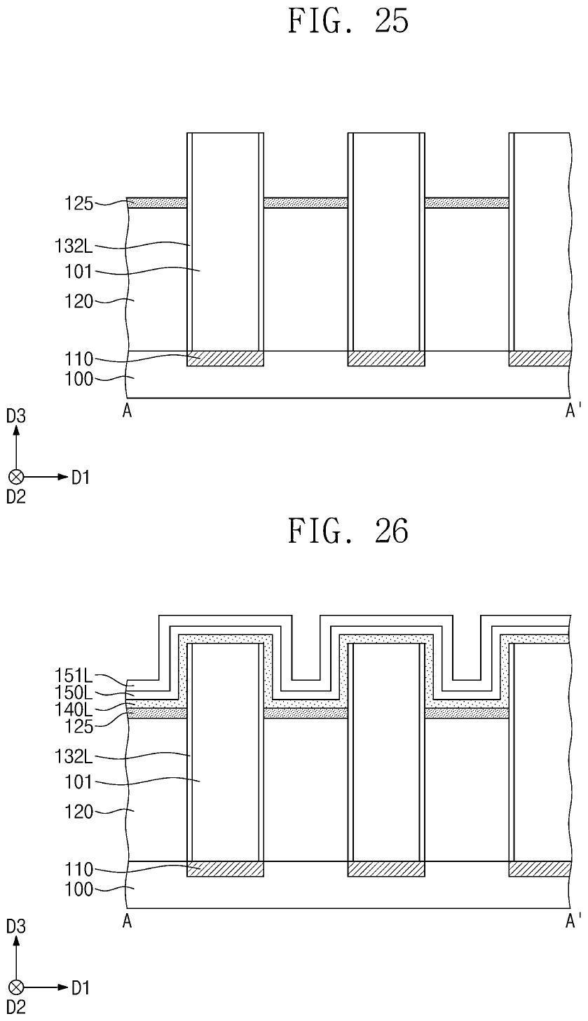

Referring to FIG. 25, the sacrificial layer SL may be removed. The sacrificial layer SL may be removed by a wet etching process. During the removal of the sacrificial layer SL, the sacrificial pillars 101, the second sub-magnetic layer 132L, and the etch stop layer 125 may not be removed due to their etch selectivity.

Referring to FIG. 26, a tunnel barrier layer 140L, a second magnetic layer 150L, and a capping layer 151L may be sequentially formed. The tunnel barrier layer 140L, the second magnetic layer 150L, and the capping layer 151L may extend onto the etch stop layer 125, while conformally covering lateral and top surfaces of the second sub-magnetic layer 132L and the top surface of the sacrificial pillar 101.

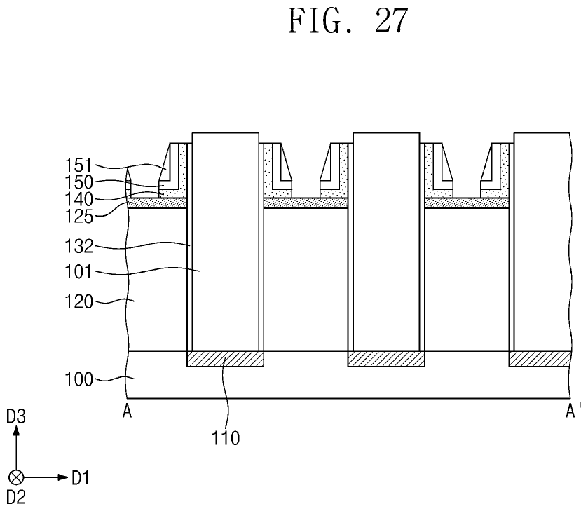

Referring to FIG. 27, there may be formed a tunnel barrier pattern 140, a second magnetic pattern 150, and a capping pattern 151. The tunnel barrier pattern 140, the second magnetic pattern 150, and the capping pattern 151 may be formed by an anisotropic etching process. The capping pattern 151 may be formed on a lateral surface of the second magnetic pattern 150. In the anisotropic etching process, a second sub-magnetic pattern 132 may be formed. An upper portion of the second sub-magnetic layer 132L may be partially removed to form the second sub-magnetic pattern 132. The second magnetic pattern 150, the tunnel barrier pattern 140, and the second sub-magnetic pattern 132 may have their top surfaces that are substantially coplanar with each other.

Referring back to FIG. 23, there may be formed a first magnetic pattern 130, a dielectric pillar 300, a second dielectric pattern 200, a second wiring layer 210, and an upper dielectric pattern 220. A magnetic memory device of FIG. 23 may be fabricated through substantially the same process as that discussed with reference to FIGS. 9 to 14.

According to the present inventive concepts, in a case where the second sub-magnetic pattern 132 is included, the tunnel barrier pattern 140 may be prevented from contamination. In a case where the process of FIGS. 24 to 27 is used for fabrication, the tunnel barrier pattern 140 may be prevented from being in contact with an etching solution for removing the sacrificial pillar 101. This may be caused by the fact that the second sub-magnetic pattern 132 is already formed on a lateral surface of the tunnel barrier pattern 140. Accordingly, a magnetic memory device may have improved electrical properties and increased reliability.

According to the present inventive concepts, a non-crooked vertical free layer may be formed to provide a magnetic memory device with improved electrical properties and increased reliability.

According to the present inventive concepts, it may be possible to provide a magnetic memory device having a vertical free layer that is more easily achieved commercially in the present technical level.

The aforementioned description provides some embodiments for explaining the present inventive concepts. Therefore, the present inventive concepts are not limited to the embodiments described above, and it will be understood by those of ordinary skill in the art that variations in form and detail may be made therein without departing from the scope of the present inventive concepts.

What is claimed is:

1. A magnetic memory device, comprising:
a substrate;
a first dielectric pattern on the substrate;
a dielectric pillar including a penetration part that penetrates the first dielectric pattern and a protrusion part that protrudes above a top surface of the first dielectric pattern;
a first magnetic pattern between the first dielectric pattern and the dielectric pillar, the first magnetic pattern including a first part that surrounds a lateral surface of the penetration part and a second part that surrounds a lateral surface of the protrusion part;
a second magnetic pattern on the first dielectric pattern, the second magnetic pattern surrounding a lateral surface of the second part; and
a tunnel barrier pattern on the first dielectric pattern and between the second part and the second magnetic pattern,
wherein the first magnetic pattern extends along a vertical direction that is perpendicular to a top surface of the substrate.

2. The magnetic memory device of claim 1, wherein the first magnetic pattern includes a plurality of magnetic domains arranged in the vertical direction, and wherein the second magnetic pattern has a magnetization direction that is fixed in one direction.

3. The magnetic memory device of claim 1, further comprising an etch stop layer between the first dielectric pattern and a bottom surface of the tunnel barrier pattern,
wherein the etch stop layer extends onto the top surface of the first dielectric pattern and contacts an outer sidewall of the first magnetic pattern.

4. The magnetic memory device of claim 1, wherein the second magnetic pattern includes:
a vertical part that extends along the vertical direction; and
a horizontal part that protrudes along a horizontal direction from a lower portion of the vertical part, the horizontal direction away from the dielectric pillar.

5. The magnetic memory device of claim 4, wherein the tunnel barrier pattern includes:
a vertical part that extends along the vertical direction; and
a horizontal part that protrudes along the horizontal direction from a lower portion of the vertical part of the tunnel barrier pattern,
wherein the vertical part of the tunnel barrier pattern is between the dielectric pillar and the vertical part of the second magnetic pattern, and
wherein the horizontal part of the tunnel barrier pattern is between the first dielectric pattern and the horizontal part of the second magnetic pattern.

6. The magnetic memory device of claim 5, wherein a lateral surface of the horizontal part of the second magnetic pattern is aligned in the vertical direction with a lateral surface of the horizontal part of the tunnel barrier pattern.

7. The magnetic memory device of claim 1, further comprising a first sub-magnetic pattern between the tunnel barrier pattern and the second part of the first magnetic pattern.

8. The magnetic memory device of claim 7,
wherein the second magnetic pattern includes:
a vertical part that extends in the vertical direction; and
a horizontal part that protrudes in a horizontal direction from a lower portion of the vertical part of the second magnetic pattern, the horizontal direction away from the dielectric pillar,
wherein the tunnel barrier pattern includes:
a vertical part that extends in the vertical direction; and
a horizontal part that protrudes in the horizontal direction from a lower portion of the vertical part of the tunnel barrier pattern,
wherein the first sub-magnetic pattern includes:
a vertical part that extends in the vertical direction; and
a horizontal part that protrudes in the horizontal direction from a lower portion of the vertical part of the first sub-magnetic pattern.

9. The magnetic memory device of claim 8, wherein a lateral surface of the horizontal part of the second magnetic pattern, a lateral surface of the horizontal part of the tunnel barrier pattern, and a lateral surface of the horizontal part of the first sub-magnetic pattern are aligned with each other in the vertical direction.

10. The magnetic memory device of claim 7, further comprising an etch stop layer between the first dielectric pattern and a bottom surface of the first sub-magnetic pattern,
wherein the etch stop layer extends onto the top surface of the first dielectric pattern and contacts an outer sidewall of the first magnetic pattern.

11. A magnetic memory device, comprising:
a substrate;
a first dielectric pattern on the substrate; and
a plurality of vertical structures that penetrate the first dielectric pattern,
wherein the vertical structures are spaced apart from each other in a first direction and a second direction that are parallel to a top surface of the substrate and intersect each other,
wherein each of the vertical structures includes:
a dielectric pillar including a penetration part that penetrates the first dielectric pattern and a protrusion part that protrudes above a top surface of the first dielectric pattern;
a first magnetic pattern between the first dielectric pattern and the dielectric pillar, the first magnetic pattern including a first part that surrounds a lateral surface of the penetration part and a second part that surrounds a lateral surface of the protrusion part;
a second magnetic pattern on the first dielectric pattern, the second magnetic pattern surrounding a lateral surface of the second part; and
a tunnel barrier pattern on the first dielectric pattern and between the second part and the second magnetic pattern, and
wherein each of the first magnetic patterns extends in a third direction perpendicular to the top surface of the substrate.

12. The magnetic memory device of claim 11, further comprising a second dielectric pattern between the second magnetic patterns, the second dielectric pattern extending onto the top surface of the first dielectric pattern.

13. The magnetic memory device of claim 12, further comprising:
a plurality of first wiring layers that extend in the second direction and are spaced apart from each other in the first direction, top surfaces of the first wiring layers are correspondingly in contact with bottom surfaces of the first magnetic patterns of the vertical structures that are spaced apart from each other in the second direction; and
a plurality of second wiring layers that extend in the first direction and are spaced apart from each other in the second direction on the second dielectric pattern, the second wiring layers correspondingly between the second magnetic patterns of the vertical structures that are spaced apart from each other in the first direction.

14. The magnetic memory device of claim 13, further comprising a plurality of separation dielectric patterns that extend in the first direction between the second wiring layers and are spaced apart from each other in the second direction.

15. The magnetic memory device of claim 11, wherein each of the vertical structures further includes a first sub-magnetic pattern between the tunnel barrier pattern and the second part of each of the first magnetic patterns.

16. The magnetic memory device of claim 15,
wherein the second magnetic pattern includes:
a vertical part that extends in the third direction; and
a horizontal part that protrudes in a horizontal direction from a lower portion of the vertical part of the second magnetic pattern, the horizontal direction being away from the dielectric pillar,
wherein the tunnel barrier pattern includes:
a vertical part that extends along the third direction; and
a horizontal part that protrudes along the horizontal direction from a lower portion of the vertical part of the tunnel barrier pattern, and
wherein the first sub-magnetic pattern includes:
a vertical part that extends along the third direction; and
a horizontal part that protrudes along the horizontal direction from a lower portion of the vertical part of the first sub-magnetic pattern.

17. The magnetic memory device of claim 16, wherein a lateral surface of the horizontal part of the second magnetic pattern, a lateral surface of the horizontal part of the tunnel barrier pattern, and a lateral surface of the horizontal part of the first sub-magnetic pattern are aligned with each other in the third direction.

18. A magnetic memory device, comprising:
a substrate including a first wiring layer that extends in a second direction;
a first dielectric pattern on the substrate;
a dielectric pillar on the first wiring layer, the dielectric pillar including a penetration part that penetrates the first dielectric pattern and a protrusion part that protrudes above a top surface of the first dielectric pattern;
a first magnetic pattern between the first dielectric pattern and the dielectric pillar on the first wiring layer, the first magnetic pattern including a first part that surrounds a lateral surface of the penetration part and a second part that surrounds a lateral surface of the protrusion part;
a second magnetic pattern on the first dielectric pattern, the second magnetic pattern surrounding a lateral surface of the second part;
a tunnel barrier pattern on the first dielectric pattern and between the second part and the second magnetic pattern;
a second dielectric pattern on the first dielectric pattern, the second dielectric pattern surrounding a lower lateral surface of the second magnetic pattern on the first dielectric pattern;
a second wiring layer on the second dielectric pattern, the second wiring layer surrounding an upper lateral surface of the second magnetic pattern; and
an upper dielectric pattern that covers a top surface of the tunnel barrier pattern, a top surface of the second magnetic pattern, and a top surface of the second wiring layer,
wherein the first magnetic pattern extends in a vertical direction perpendicular to a top surface of the substrate.

19. The magnetic memory device of claim 18,
wherein the second magnetic pattern includes:
a vertical part that extends along the vertical direction; and
a horizontal part that protrudes along a horizontal direction from a lower portion of the vertical part of the second magnetic pattern, the horizontal direction being away from the dielectric pillar, and
wherein the tunnel barrier pattern includes:
a vertical part that extends along the vertical direction; and
a horizontal part that protrudes along the horizontal direction from a lower portion of the vertical part of the tunnel barrier pattern.

20. The magnetic memory device of claim 19, wherein a lateral surface of the horizontal part of the second magnetic pattern and a lateral surface of the horizontal part of the tunnel barrier pattern are aligned with each other in the vertical direction.
